(19) United States
(12) Patent Application Publication
(10) Pub. No.: US 2012/0056016 A1
(43) Pub. Date: Mar. 8, 2012

(54) ADVANCED SPRAY BOTTLE WITH SYNCLINED FLOOR

(76) Inventors: William Fritsch, Madison, WI (US); Robert J. Gold, El Mirage, AZ (US)

(21) Appl. No.: 12/876,534

(22) Filed: Sep. 7, 2010

(51) Int. Cl. H05K 13/00

(52) U.S. Cl. 239/302

(57) ABSTRACT

An advanced spray bottle facilitates complete emptying of liquid in its container even as the container is rotated and tilted. The container has a primary chamber with a raised floor that has a syncline shape and that forms a sluice channel. The raised floor slopes downward across the container to route fluids to a lowest point of the sluice channel. An indent in the container provides a cavity for further capture and concentration of liquids. The container is shaped to guide a bottom aperture of the uptake tube to the lowest point of the sluice channel. The bottom aperture of the uptake tube is angled so as to better fit within the lowest point of the sluice channel. A secondary chamber at the base of the container, with an egress to the primary chamber holds additional solids and liquids. Alternate add-on bases for the container provide additional functionality.

### FIELD OF THE INVENTION

This invention relates generally to fluid dispensing containers, and more specifically to advanced spray bottles designed to facilitate access to the entire content of the bottle.

### DESCRIPTION OF THE PRIOR ART

Spray bottles of various sizes can be found in households, industry, the government, and the military. They allow for the dissemination of fluids through spray action for a variety of uses, including cleaning, polishing, and chemical application. Spray bottles on the market, however, suffer from substantial shortcomings. For example, when the level of liquid in a spray bottle is low, the tube that transfers the liquid up to the sprayer mechanism is often not in contact with a sufficient amount of liquid to ensure reliable spray action. Also, tilting the container so as to orient the spray nozzle head at a desired target often reorients the liquid in the container so that the liquid is not positioned to ensure reliable spray action. As such, a significant amount of the liquid in a spray bottle can become inaccessible to a user unless the spray bottle is disassembled. Moreover, additional items such as wipes and auxiliary chemicals are not readily at hand. What is needed is a spray bottle that overcomes these and other shortcomings.

### SUMMARY OF THE INVENTION

The present invention provides an advanced spray bottle in the form of an exemplary spray bottle assembly 10. Referring to FIGS. 1 and 2, spray bottle assembly 10 comprises a container 20 having a first side 23 and a second side 22 opposite the first side. The container 20 includes a top collar 24 and a sidewall 21, the sidewall 21 having an inner surface 21a and an outer surface 21b. Container 20 also includes a raised floor 28 with a syncline shape at 28a, and a level bottom edge 27 located below the raised floor 28. A first chamber 53 is formed between top collar 24 and raised floor 28, encompassed by the inner surface 21a of sidewall 21. A second chamber 26, situated below the first chamber 53, is formed between raised floor 28 and bottom edge 27, and is also encompassed by the inner surface 21a of sidewall 21. The syncline shape at 28a of the raised floor 28 forms a sluice channel 29 from the first side 23 of the container 20 to the second side 22 of the container 20.

The spray bottle assembly 10 may further include a sprayer assembly 40 with a main spray head 41, a sprayer nozzle 44 with a spray port 45, a spray trigger 43, and a spray head internal tube 46. Spray head internal tube 46 attaches to main spray head 41. In spray bottle assembly 10, sprayer assembly 40 attaches to container 20.

Raised floor 28 of container 20 has a downward slope from the first side 23 of container 20 to the second side 22 of container 20. Because of the downward slope, sluice channel 29 is at a higher elevation at the first side 23 of container 20 than at the second side 22 of container 20, facilitating fluid accumulation. An indent 50 may also be situated at the second side 22 of container 20 to further aid in fluid accumulation as container 20 is tilted.

A swivel adaptor 47 attaches to spray head internal tube 46, and an uptake tube 30 attaches to swivel adaptor 47. The first side 23 of container 20 is curved inward toward the second side 22 such that the uptake tube 30 is pushed toward the second side 22. Uptake tube 30 includes a bottom aperture 34 located at a lowest point 33 of sluice channel 29. The bottom aperture 34 of uptake tube 30 is angled in proportion to the syncline shape at 28a of the raised bottom 28 to enhance access to accumulated fluid.

The above spray bottle assembly 10 facilitates the most complete emptying of the liquid in container 20 even as container 20 is tilted and rotated by a user. Because of the downward slope of raised bottom 28, and because of the syncline shape at 28a, container 20 accumulates even very small quantities of fluid at lowest point 33 of sluice channel 29. The curved uptake tube 30 and the curved first side 23 of container 20 help position the bottom aperture 34 of uptake tube 30 at the lowest point 33 of sluice channel 29 to permit access to all the accumulated fluid. The angled shape of bottom aperture 34 ensures that uptake tube 30 can access the fluid at the very bottom of sluice channel 29. Indent 50 forms a secondary cavity 54 for holding fluid at the lowest point 33 of sluice channel 29 even as the user tilts and rotates container 20. Indent 50 may also serve as a storage adaptor that permits spray bottle assembly 10, for example, to be hung from a hook or a rung of a ladder. Moreover, second chamber 26 below first chamber 53 holds additional solids, particulate matter, liquids, and applicators for use with the content of the first chamber 53.

The objects and advantages of the invention will appear more fully from the following detailed description of the preferred embodiment of the invention made in conjunction with the accompanying drawings.

### BRIEF DESCRIPTION OF THE DRAWINGS

Features, aspects, and advantages of exemplary versions of the present invention may be demonstrated by the following non-limiting figures, in which:

FIG. 1 is a perspective rear-angled view of one exemplary spray bottle assembly of the present invention;

FIG. 2a is a back plan view of the spray bottle assembly of FIG. 1;

FIG. 2b is a side plan view of the spray bottle assembly of FIG. 1;

FIG. 2c is a front plan view of the spray bottle assembly of FIG. 1;

FIG. 3 illustrates a rear plan view of the spray bottle assembly of FIG. 2a showing three cut-away views illustrating alternative internal sluice configurations:

FIG. 3a is a cut-away of a first embodiment of the bottom section of the spray bottle assembly of FIG. 2a, taken at line 71 of FIG. 3, and shows a “V” shaped sluice channel;

FIG. 3b is a cut-away of a second embodiment of the bottom section of the spray bottle assembly of FIG. 2a, taken at line 71 of FIG. 3, and shows a “curve” shaped sluice channel;

FIG. 3c is a cut-away of a third embodiment of the bottom section of the spray bottle assembly of FIG. 2a, taken at line 71 of FIG. 3, and shows a “rectangular” shaped sluice channel;

FIGS. 4a and 4b illustrate perspective views of the spray bottle assembly of FIG. 2a with first alternate cut-away views: FIG. 4c, taken at line 73 of FIG. 4a, and FIG. 4d, taken at line 74 of FIG. 4b, respectively.

FIGS. 5a and 5b illustrate perspective views of alternative embodiments of the spray bottle assembly of FIG. 2a with second alternate cut-away views: FIG. 5c, taken at line 76 of FIG. 5a, and FIG. 5d, taken at line 77 of FIG. 5b, respectively:

FIGS. 6a and 6b illustrate alternate perspective views of the spray bottle assembly of FIG. 2a with an attached base add-on, and with alternate cut-away views: FIG. 6c, taken at line 92 of FIG. 6a, and FIG. 6d, taken at line 93 of FIG. 6b, respectively:

FIGS. 7a and 7b illustrates alternate perspective views of the spray bottle assembly of FIG. 2a with an attached base add-on and with alternate cut-away views: FIG. 7c, taken at line 100 of FIG. 7a, FIG. 7d, taken at line 101 of FIG. 7b, and FIG. 7e, taken at line 102 of FIG. 7b, respectively.

### DETAILED DESCRIPTION OF THE INVENTION

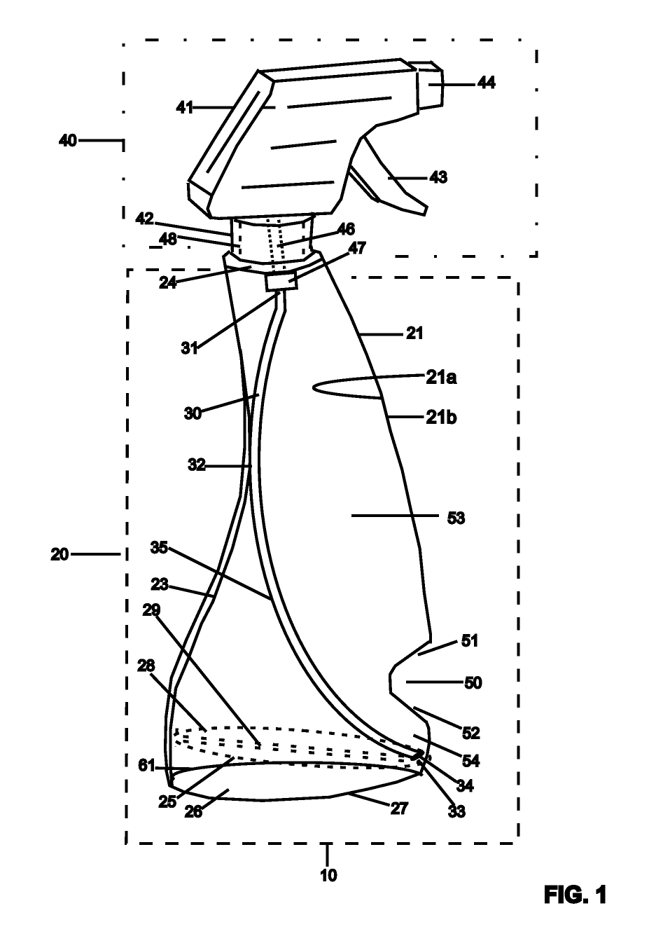

An exemplary spray bottle assembly 10 is shown in FIG. 1. Spray bottle assembly 10 includes a container 20 attached to a sprayer assembly 40 via a screw-on cap 42, where screw-on cap 42 attaches to container 20 via cap-container interface threads 48. Sprayer assembly 40 includes a main spray head 41, spray trigger 43, and sprayer nozzle 44. Screw-on cap 42 houses spray head internal uptake tube 46, which attaches to swivel adaptor 47.

Spray bottle assembly 10 includes an uptake tube 30 attached to sprayer assembly 40 through swivel adaptor 47. The bottom of swivel adaptor 47 attaches to a top connector section 31 of uptake tube 30. Uptake tube 30 is inserted into container 20 substantially perpendicular to the base of screw-on cap 42, where it seats against a top collar 24 of container 20. Uptake tube 30 has a curvature 35 and a bottom aperture 34. The curvature 35 of uptake tube 30 provides a contact point 32 with container 20. Swivel adaptor 47 permits main spray head 41 to rotate without changing the position of uptake tube 30 within container 20.

Container 20 of spray bottle assembly 10 includes a raised floor 28 and a bottom edge 27 below raised floor 28. The bottom edge 27 is level so that container 20 may rest on a platform (not pictured) without tipping over. Bottom edge 27 has a rim 61 that can accept a bottom cap 60 (not shown in this view). Raised floor 28 connects to the container 20 at floor edge 25. A first chamber 53 is situated between top collar 24 and raised floor 28, and a second chamber 26 is located between raised floor 28 and bottom edge 27. A sidewall 21 includes an inner surface 21a facing the first chamber 53 and the second chamber 26, and an outer surface 21b facing the outside of spray bottle assembly 10. Sidewall 21 holds the contents of first chamber 53 and second chamber 26 within container 20.

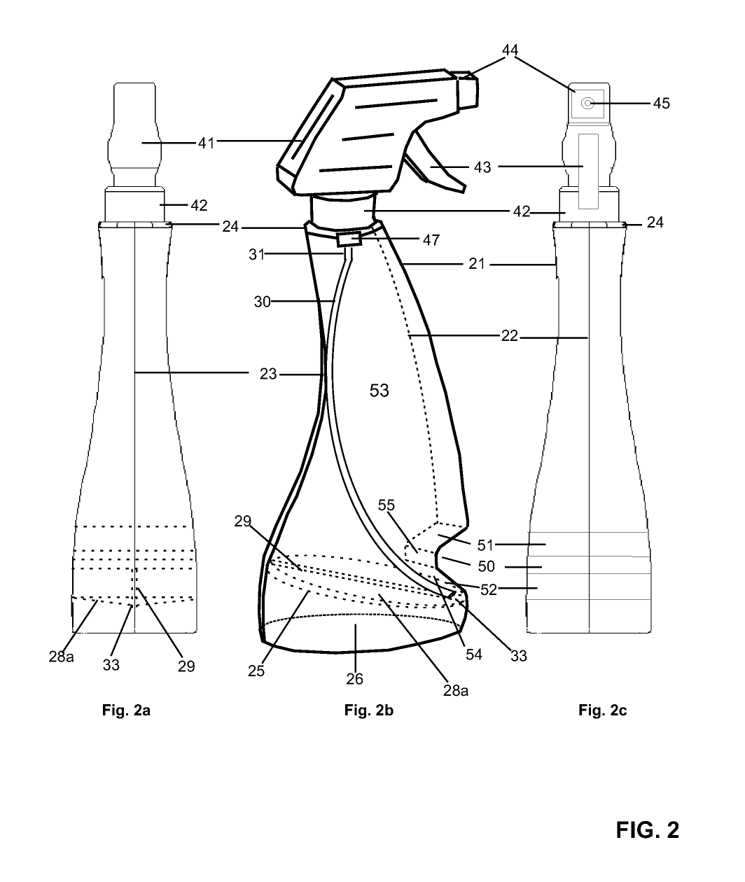

Referring to FIG. 2, container 20 includes a first side 23, a second side 22 opposite the first side 23, and a syncline shape at 28a for raised floor 28. As can be seen in FIG. 1, the first side 23 of container 20 is curved inward toward second side 22. The syncline shape at 28a forms a sluice channel 29 in raised floor 28 for accumulating the fluid in container 20. Raised floor 28 also has a downward slope from first side 23 to second side 22. This provides a lowest point 33 of sluice channel 29, where even small amounts of fluid can accumulate. The curved first side 23 presses against uptake tube 30 at contact point 32 such that bottom aperture 34 remains at lowest point 33. The bottom aperture 34 of uptake tube 30 is additionally angled so that it better mates with the syncline shape at 28a of sluice channel 29. Such positioning of the angled bottom aperture 34 at lowest point 33 permits spray bottle assembly 10 to act on extremely low levels of fluid in container 20.

The second side 22 of container 20 may include an indent 50 with a top slope 51 and a bottom slope 52. Indent 50 provides a secondary cavity 54 for holding fluid when container 20 is being tilted by a user. The size of secondary cavity 54 can be increased or decreased by enlarging or shrinking indent 50, respectively. Indent 50 is positioned at the second side 22 so that the fluid that accumulates at lowest point 33 of sluice channel 29 can be captured within secondary cavity 54 despite the orientation of container 20. Bottom aperture 34 of uptake tube 30, when located at the lowest point 33 of sluice channel 29, is below bottom slope 52 of indent 50. Secondary cavity 54, provided by indent 50, acts as a supplementary area of containment such that fluid in container 20 can be captured and made available for passage through uptake tube 30 via bottom aperture 34.

Referring to FIG. 2a, a rear view of the spray bottle assembly 10 of FIG. 1 shows the syncline shape at 28a of raised floor 28. Sluice channel 29 is shown vertically, representing the downward slope from the first side 23 (visible in FIG. 2a) of container 20 to the second side 22 (hidden in FIG. 2a, visible in FIG. 2c). As such, sluice channel 29 begins at a higher elevation at the first side 23 of container 20 and terminates at lowest point 33. Because of the downward slope, the fluid in container 20 is gravitationally drawn along sluice channel 29 to lowest point 33.

FIG. 2b shows the sluice channel 29 of downward sloping raised floor 28. Also shown in FIG. 2b is a middle indent section 55 of indent 50. In FIG. 2c, sprayer nozzle 44 is shown including a spray port 45, out of which the fluid in container 20 sprays. FIG. 2c also shows a front-view outline of indent 50.

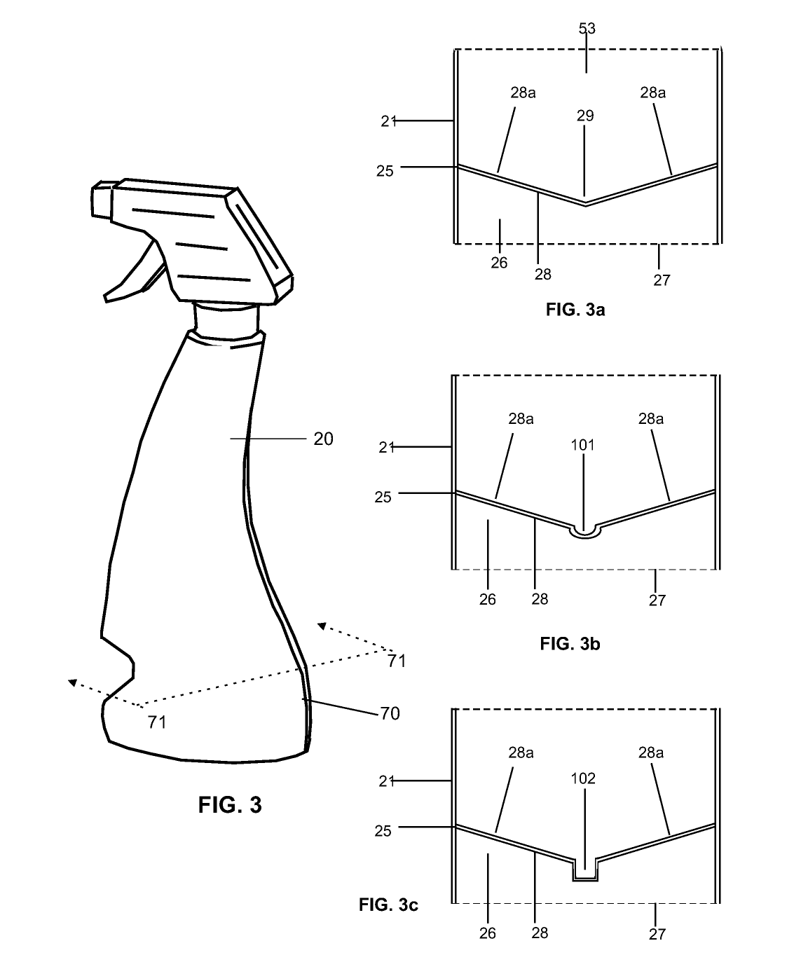

A rear-view of spray bottle assembly 10 is shown in FIG. 3. FIGS. 3A, 3B and 3C of bottom portion 70 of container 20 are depicted and show three variations of the sluice channel configuration. Depicted in FIG. 3A is a cross section of raised bottom 28 attached to sidewall 21 at floor edge 25. Sluice channel 29 is shown with the syncline shape at 28a forming a “V” shape. Depicted in FIG. 3B is a cross section of raised bottom 28 attached to sidewall 21 at floor edge 25. Sluice channel 101 is shown with the syncline shape at 28a forming a curved shape. Depicted in FIG. 3C is a cross section of raised bottom 28 attached to sidewall 21 at floor edge 25. Sluice channel 102 is shown with the syncline shape at 28a forming a rectangular shape. In effect, the syncline shape at 28a of raised floor 28 provides a downward “dip,” away from top collar 24 toward bottom edge 27, for accumulating small amounts of fluid. It is also noted that floor edge 26 is at a higher elevation than the bottom of the dip of sluice channel 29, so that fluid in first chamber 53 is gravitationally drawn to the bottom of sluice channel 29.

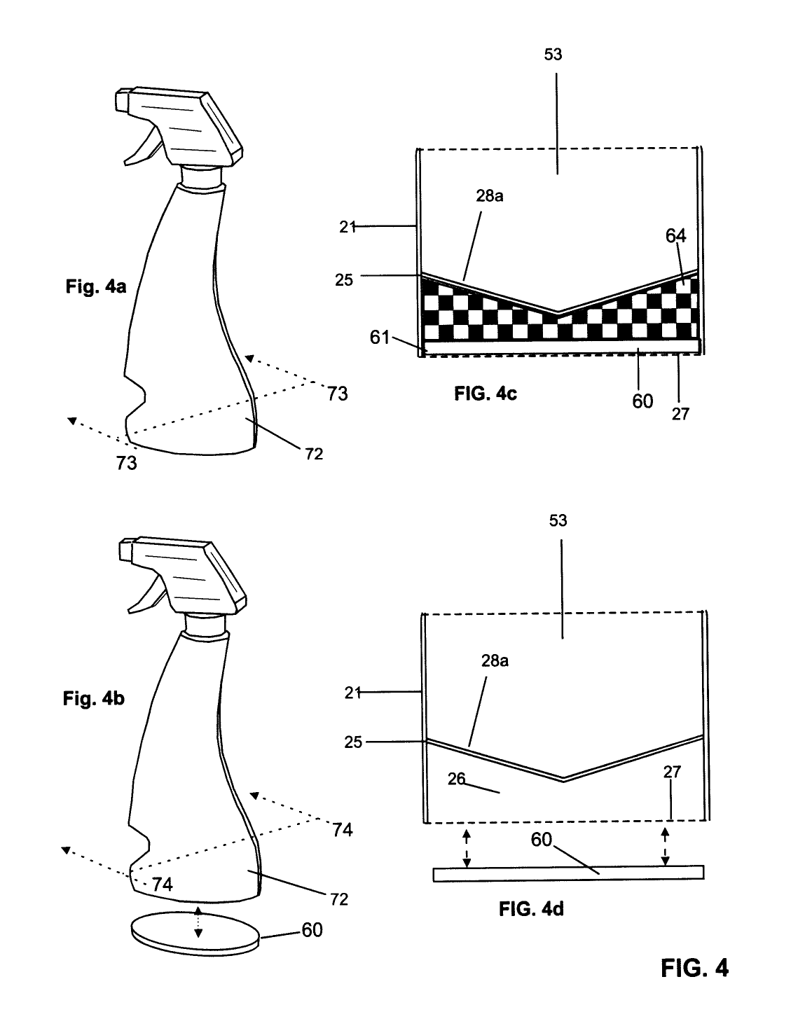

FIGS. 4a and 4b depict cut-away views FIG. 4c and FIG. 4d, respectively, of the bottom portion FIG. 4a and FIG. 4b, showing two alternative exemplary versions of spray bottle assembly 10.

Cut-away view FIG. 4c depicts a rear view of an exemplary bottom portion 72 of container 20. First chamber 53 is shown with the syncline shape at 28a of raised bottom 28 attached to sidewall 21 at floor edge 25. In this version, a solid, liquid, or particulate 64 is shown in the second chamber 26 between the syncline shape at 28a of the raised bottom 28 and the bottom edge 27 of container 20. Rim 61 of bottom cap 60 spans the circumference of bottom edge 27, and bottom cap 60 acts as a retention device for solid, liquid, or particulate 64. Solid, liquid, or particulate 64 may be dispensable by the removal of bottom cap 60.

Cut-away view FIG. 4d depicts a rear view of another exemplary bottom portion 72 of container 20. In this version, second chamber 26 is shown empty of any solid, liquid, or particulate 64. Bottom cap 60 is shown separated from second chamber 26 and bottom edge 27 of container 20.

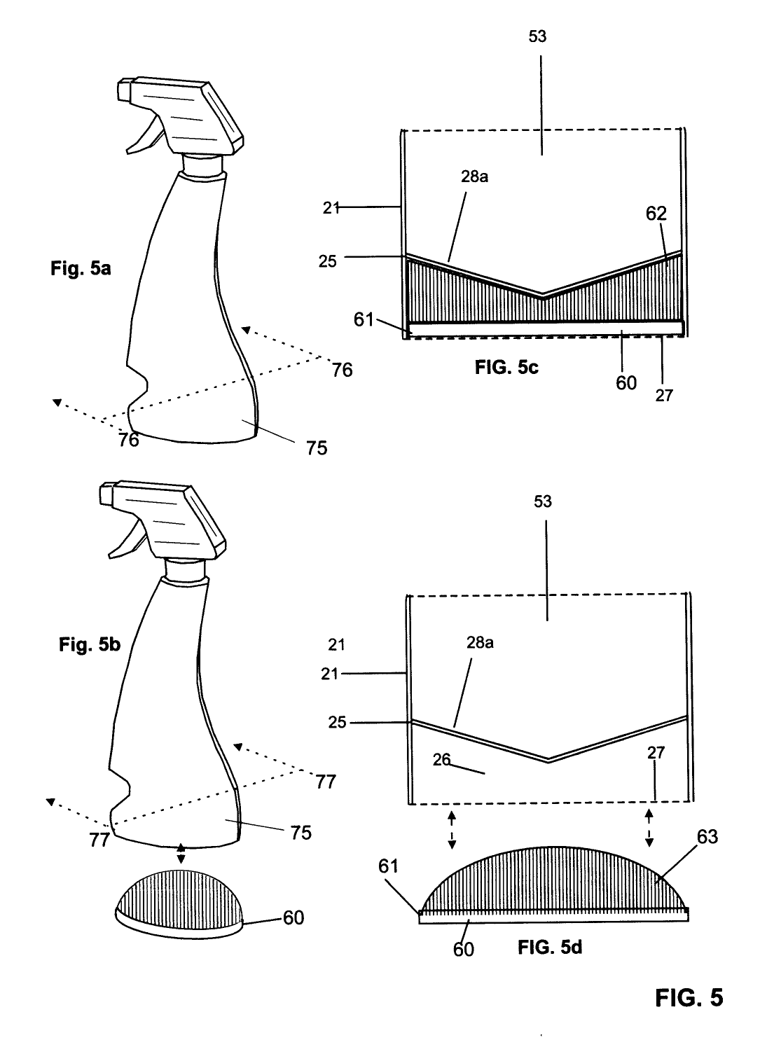

FIG. 5a and FIG. 5b depict views cut-away views FIG. 5c and FIG. 5d, respectively, of bottom portion 75, showing two additional exemplary versions of spray bottle assembly 10.

Cut-away view FIG. 5c shows the bottom portion 75 of container 20 with a cross section of raised bottom 28 attached to sidewall 21 at floor edge 25. In this version, second chamber 26 includes a compressed applicator 62. Bottom cap 60 acts as a retention device for compressed applicator 62.

Cut-away view FIG. 5d depicts a rear view of another version of bottom portion 75. In this version, second chamber 26 is shown empty. An uncompressed applicator 63 attached to bottom cap 60 is shown free of its confinement within the second chamber 26. The removal of the applicator 63 attached to bottom cap 60 allows the applicator 63 to expand from it stored size of FIG. 5c to its expanded size of FIG. 5d. Applicator 63 may be usable with the content of first chamber 53 or with the solid, liquid, or particulate 64 stored in second chamber 26.

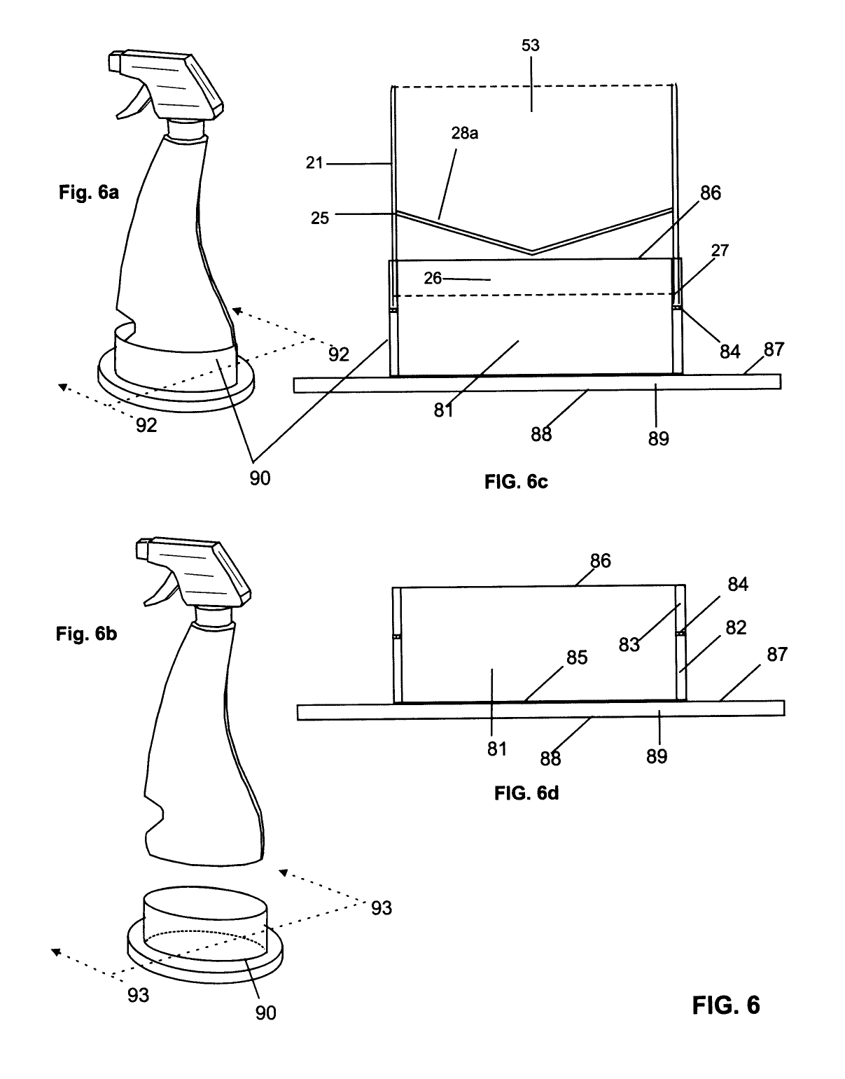

FIGS. 6a and 6b depict cut-away views 92 and 93 depicting two further exemplary versions of spray bottle assembly 10.

Cut away view FIG. 6c shows a base add-on 90 (shown as cut-away view FIG. 6d in FIG. 6b) attached to the bottom edge 27 of container 20. In FIG. 6c, bottom edge 27 of container 20 is inserted into, and is parallel with, base add-on 90. Base add-on 90 in FIGS. 6a and 6b has an interior space 81 and an exterior wall 82, and exterior wall 82 includes a hollow wall interior 83. Bottom edge 27 of container 20 butts against, and has its movement stopped by, an interior boss 84. Placement of bottom edge 27 into interior space 81 creates a uniform seal between bottom edge 27 and base add-on 90, such that base add-on 90 acts as a new bottom surface for container 20. This bottom surface includes a base pad 89 having a bottom side 88. Base pad 89 enlarges the overall footprint of container 20, as a top side 87 of base pad 89 projects outward parallel with the bottom side 88. Such outward projection results in a broad base, serving to stabilize container 20 when placed on uneven or tilted surfaces. The bottom side 88 of base pad 89 can also have a traction-enhancing non-slip surface (not shown) so that container 20 can be placed on a wet or moving surface without slipping.

This arrangement also provides a large cavity, comprising interior space 81 and second chamber 26, between raised bottom 28 and an interior bottom 85 of base add-on 90. Here, base add-on 90, which includes top edge 86, forms a sealed container that is capable of holding a solid, liquid, or particulate 64 within its confines.

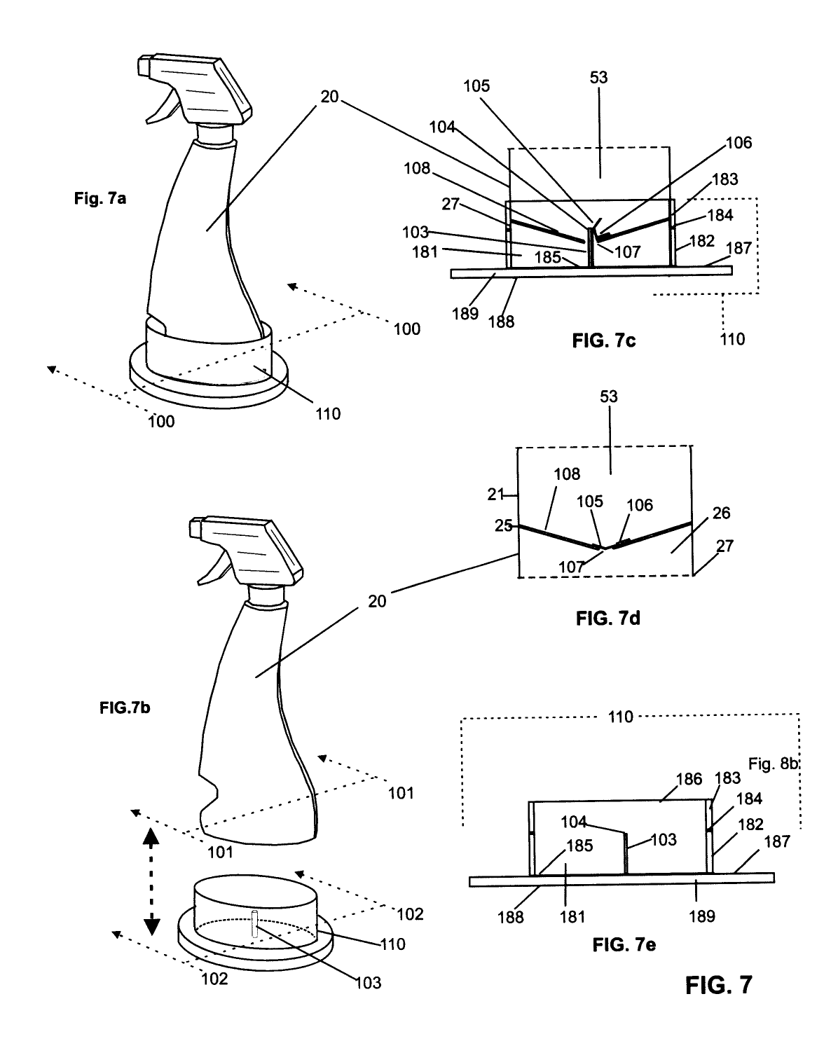

FIG. 7a and FIG. 7b show a base add-on 110 shown as a cut-away view in FIG. 7c and FIG. 7e. FIG. 7d shows a cut-away view depicting the bottom portion 101 of container 20 of a variant version of spray bottle assembly 10.

Cut-away view FIG. 7c depicts the union of the two parts of a dual chamber access system of a variant version of spray bottle assembly 10.

Cut-away view FIG. 7d and FIG. 7e depict the two separate parts of a dual chamber access system of a variant version of spray bottle assembly 10.

Cut away FIG. 7c shows a base add-on 110 (shown individually as FIG. 7e and attached to the container 20 in cut-away view FIG. 7c) attached to the bottom edge 27 of container 20. In FIG. 7a, bottom edge 27 of container 20 is inserted into, and is parallel with, base add-on 110. Base add-on 110 in FIGS. 7c and 7e has an interior space 181 and an exterior wall 182, and exterior wall 182 includes a hollow wall interior 183. Bottom edge 27 of container 20 butts against, and has its movement stopped by, an interior boss 184. Placement of bottom edge 27 into interior space 181 creates a uniform seal between bottom edge 27 and base add-on 110, such that base add-on 110 acts as a new bottom surface for container 20. This bottom surface includes a base pad 189 having a bottom side 188. Base pad 189 enlarges the overall footprint of container 20, as a top side 187 of base pad 189 projects outward parallel with the bottom side 188. Such outward projection results in a broad base, serving to stabilize container 20 when placed on uneven or tilted surfaces. The bottom side 188 of base pad 189 can also have a traction-enhancing non-slip surface (not shown) so that container 20 can be placed on a wet or moving surface without slipping.

In this variant of spray bottle assembly 10, as shown in cut-away view FIG. 7e, the base add-on 110 has a central vertical post 103 protruding from the interior bottom 185 of base add-on 110. When the base add-on 110 is placed on the bottom of container 20 as shown in FIG. 7a and cut-away view FIG. 7c the tip 104 of the central vertical post 103 protrudes from the interior bottom 185 of base add-on 110 to a length which impacts a flap seal 105 which covers opening 107 and central vertical post 103 passes through opening 107 in the interior raised bottom 108 of the container 20. When central vertical post 103 passes through opening 107 it forces the flap seal 105 in the interior raised bottom 108 of the container 20 to open via its hinge 106. The flap seal 105 is normally sealed via its hinge 106 to the interior raised bottom 108 of the container 20 as shown in cut-away view FIG. 7d of FIG. 7b. The flap seal 105 is attached to the upper surface of raised bottom 108 of the first chamber 53 in a manner which covers and seals the opening 107 and the weight of the solid, liquid, or particulate 64 contents of first chamber 53 holds flap seal 105 in communication with the raised bottom 108 and seals opening 107. When flap seal 105 is held open by central vertical post 103, as shown in FIG. 7c, the opening 107 can communicate solid, liquid, or particulate 64 contents from first chamber 53 to the second chamber 181 which is created by the joining of base add-on 110 to container 20. The base add-on 110 may be removed from the bottom of container 20, as shown in FIG. 7b, to refill its contents. When the base add-on 110 is removed from the bottom of container 20, as shown in FIG. 7b the central vertical post 103 is withdrawn from the opening 107 and flap seal 105 via its hinge 106 reseals opening 107, as shown in FIG. 7d, and prevents egress of any further solid, liquid, or particulate 64 content from first chamber 53.

It is understood that the invention is not confined to the particular construction and arrangement of parts herein illustrated and described, but embraces such modified forms thereof as come within the scope of the following claims.

What is claimed is:

1. A spray bottle assembly for dispensing fluid, comprising a container having a first side and a second side opposite the first side, the container comprising:
a) a top collar;
b) a sidewall with an inner surface and an outer surface;
c) a raised floor with a syncline shape;
d) a first chamber situated between the top collar, the inner surface of the sidewall, and the raised floor;
e) a level bottom edge located below the raised floor; and
f) a second chamber situated between the raised floor, the inner surface of the sidewall, and the bottom edge;
wherein the syncline shape of the raised floor forms a sluice channel from the first side of the container to the second side of the container.

2. The spray bottle assembly of claim 1, wherein:
a) the raised floor slopes downward from the first side of the container to the second side of the container, and
b) a lowest point of the sluice channel is located at the second side of the container.

3. The spray bottle assembly of claim 1, further comprising an uptake tube having a bottom aperture, wherein:
a) the uptake tube is inserted in the container through the top collar, and
b) the bottom aperture of the uptake tube is situated in the sluice channel.

4. The spray bottle assembly of claim 3, wherein the bottom aperture of the uptake tube is angled to mate with the sluice channel.

5. The spray bottle assembly of claim 3, wherein the first side of the container is curved inward toward the second side of the container such that the uptake tube is pressed toward the second side of the container.

6. The spray bottle assembly of claim 1, wherein the syncline shape of the floor is v-shaped, curved, or rectangular.

7. The spray bottle assembly of claim 1, wherein:
a) the container further comprises an indent located at the second side of the container, and
b) the indent provides a secondary cavity for holding fluid as the container tilts.

8. The spray bottle assembly of claim 1, wherein:
a) the container comprises a closure system, and
b) the closure system permits the first chamber to access the second chamber.

9. The spray bottle assembly of claim 8, wherein the closure system comprises a hole or a flap.

10. A spray bottle assembly for dispensing fluid, with a container having a first side and a second side opposite the first side, the container comprising:
a) a top collar;
b) a sidewall having an inner surface and an outer surface opposing the inner surface;
c) a raised floor;
d) a first chamber situated between the top collar, the inner surface of the sidewall, and the raised floor;
e) a bottom edge; and
f) a second chamber situated between the raised floor, the inner surface of the sidewall, and the bottom edge;
wherein the raised floor comprises an egress permitting the first chamber to access the second chamber.

11. The spray bottle assembly of claim 10, wherein the egress is controllable by a user of the spray container.

12. The spray bottle assembly of claim 10, wherein the raised floor has a downward slope from the first side of the spray container down to the second side of the spray container.

13. The spray bottle assembly of claim 10, wherein the raised floor comprises a syncline shape forming a sluice channel.

14. The spray bottle assembly of claim 13, further comprising an uptake tube having a bottom aperture, wherein:
a) the uptake tube is inserted through the top collar of the container, and
b) the sidewall is curved at the first side of the container such that:
1) the uptake tube is pushed toward the second side of the spray container, and
2) the bottom aperture of the uptake tube is positioned in the sluice channel.

15. A spray bottle assembly for dispensing fluid, comprising:
a) a sprayer assembly comprising:
1) a main spray head;
2) a sprayer nozzle with a spray port;
3) a spray trigger; and
4) a spray head internal tube attached to the main spray head;
b) a container, having a first side and a second side opposing the first side, comprising:
1) a top collar;
2) a sidewall having an inner surface and an opposing outer surface;
3) a raised bottom having a downward slope from the first side of the container to the second side of the container;
4) a first chamber situated between the top collar, the inner surface of the sidewall, and the raised bottom;
5) a bottom edge having a first area;
6) a second chamber situated below the first chamber, the second chamber situated between the raised bottom, the inner surface of the sidewall, and the bottom edge;
7) an indent situated at the second side of the container;
c) a swivel adaptor attached to the spray head internal tube;
d) a curved uptake tube attached to the swivel adaptor, the curved uptake tube comprising a bottom aperture, wherein the bottom aperture is positioned within the sluice channel at the second side of the container;
e) wherein:
1) the sprayer assembly attaches to the container,
2) the first side of the container is curved inward toward the second side such that the uptake tube is pushed toward the second side,
3) the raised bottom has a syncline shape forming a sluice channel between the first side of the container to the second side of the container, wherein the sluice channel is higher at the first side of the container than at the second side of the container,
4) a lowest point of the sluice channel is situated at the second side of the container, and
5) the bottom aperture of the uptake tube is angled in proportion to the syncline shape of the raised bottom.

16. The spray bottle assembly of claim 14, wherein the bottom aperture of the uptake tube is maintained at the lowest point of the sluice channel by:
a) the first side of the container, and
b) the swivel adaptor.

17. The spray bottle assembly of claim 14, wherein the second chamber further comprises an egress permitting access to the first chamber.

18. The spray bottle assembly of claim 14, wherein it further comprises a base add-on, wherein the base add-on attaches to the bottom edge of the container.

19. The spray bottle assembly of claim 18, wherein the base add-on comprises a platform having a second area, wherein the second area of the platform is greater than the first area of the bottom edge.
